(19) United States
(12) Patent Application Publication
(10) Pub. No.: US 2024/0213745 A1
(43) Pub. Date: Jun. 27, 2024

(54) WAVELENGTH BEAM COMBINING DEVICE

(71) Applicant: NICHIA CORPORATION, Anan-shi (JP)

(72) Inventors: Hidenori MATSUO, Hadano-shi (JP); Norihiro DEJIMA, Yokohama-shi (JP); Hisashi OGAWA, Yokohama-shi (JP)

(73) Assignee: NICHIA CORPORATION, Anan-shi (JP)

(21) Appl. No.: 18/392,438

(22) Filed: Dec. 21, 2023

(30) Foreign Application Priority Data
Dec. 26, 2022 (JP) 2022-207817

(51) Int. Cl. H01S 5/40; H01S 5/02251; H01S 5/02253; H01S 5/14

(52) U.S. Cl. CPC H01S 5/4012; H01S 5/02251; H01S 5/02253; H01S 5/141

(57) ABSTRACT

A wavelength beam combining device includes: a plurality of light source devices; and a diffraction grating configured to perform wavelength beam combining of a plurality of laser beams emitted from the plurality of light source devices. At least one of the plurality of light source devices includes: a first light source unit including: a first external resonator formed by a first wavelength selection element and a first resonator mirror, a first light source, and a first internal optical path adjusting element, a second light source unit including: a second external resonator formed by the first wavelength selection element and a second resonator mirror, a second light source, and a second internal optical path adjusting element, a first external optical path adjusting element, and a second external optical path adjusting element.

### CROSS-REFERENCE TO RELATED APPLICATION

This application claims priority to Japanese Patent Application No. 2022-207817, filed on Dec. 26, 2022, the disclosure of which is hereby incorporated by reference in its entirety.

### TECHNICAL FIELD

The present disclosure relates to a wavelength beam combining device.

### BACKGROUND

As a technique for producing a high-power laser beam, a wavelength beam combining (WBC) technique has been developed, in which a plurality of laser beams emitted by a plurality of light source devices and having mutually different wavelengths are coaxially combined using a diffraction grating. In order to increase power, it is desirable that the wavelengths used for WBC be selected as predetermined wavelengths for increasing the number of beams to be combined and improving combining accuracy, for example. See, for example, Japanese Patent Publication No. 2021-34531.

### SUMMARY

One object of the present disclosure is to provide a wavelength beam combining device that can obtain a high-power laser beam.

In one embodiment, a wavelength beam combining device according to the present disclosure includes a plurality of light source devices, and a diffraction grating configured to perform wavelength beam combining of a plurality of laser beams emitted from the plurality of light source devices. At least one of the plurality of light source devices includes a first light source unit including a first external resonator formed by a first wavelength selection element and a first resonator mirror, with a first light source disposed in the first external resonator and configured to emit a first laser beam during laser oscillation, and with a first internal optical path adjusting element disposed between the first wavelength selection element and the first light source in the first external resonator and configured to allow the first laser beam to be incident on the first wavelength selection element. The at least one of the plurality of light source devices includes a second light source unit including a second external resonator formed by the first wavelength selection element and a second resonator mirror, with a second light source disposed in the second external resonator and configured to emit a second laser beam during laser oscillation, and with a second internal optical path adjusting element disposed between the first wavelength selection element and the second light source in the second external resonator and configured to allow the second laser beam to be incident on the first wavelength selection element. The at least one of the plurality of light source devices includes a first external optical path adjusting element disposed outside the first external resonator and configured to allow the first laser beam to be incident in a predetermined direction, and a second external optical path adjusting element disposed outside the second external resonator and configured to allow the second laser beam to be incident in a predetermined direction.

In another embodiment, a wavelength beam combining device according to the present disclosure includes a plurality of light source devices, and a diffraction grating configured to perform wavelength beam combining of a plurality of laser beams emitted from the plurality of light source devices. At least one of the plurality of light source devices includes a first light source unit including a first external resonator formed by a first wavelength selection element and a first resonator mirror, with a first light source disposed in the first external resonator and configured to emit a first laser beam during laser oscillation, and with a first internal optical path adjusting element disposed between the first wavelength selection element and the first light source in the first external resonator and configured to allow the first laser beam to be incident on the first wavelength selection element. The at least one of the plurality of light source devices includes a second light source unit including a second external resonator formed by a second wavelength selection element and a second resonator mirror, with a second light source disposed in the second external resonator and configured to emit a second laser beam during laser oscillation, and with a second internal optical path adjusting element disposed between the second wavelength selection element and the second light source in the second external resonator and configured to allow the second laser beam to be incident on the second wavelength selection element. The at least one of the plurality of light source devices includes a first external optical path adjusting element disposed outside the first external resonator and configured to allow the first laser beam to be incident in a predetermined direction, and a second external optical path adjusting element disposed outside the second external resonator and configured to allow the second laser beam to be incident in a predetermined direction.

According to certain embodiments of the present disclosure, a wavelength beam combining device can be realized that can obtain a high-power laser beam.

### BRIEF DESCRIPTION OF DRAWINGS

FIG. 1A is a view schematically illustrating a configuration of a wavelength beam combining device according to an exemplary first embodiment of the present disclosure.

FIG. 1B is a view illustrating a first example of a light source device included in the wavelength beam combining device illustrated in FIG. 1A.

FIG. 1C is a view illustrating a second example of a light source device included in the wavelength beam combining device illustrated in FIG. 1A.

FIG. 2 is a view schematically illustrating a configuration of a wavelength beam combining device according to an exemplary second embodiment of the present disclosure.

FIG. 3A is a view schematically illustrating a configuration of a wavelength beam combining device according to an exemplary third embodiment of the present disclosure.

FIG. 3B is a view illustrating a first example of a light source device included in the wavelength beam combining device illustrated in FIG. 3A.

FIG. 3C is a view illustrating a second example of a light source device included in the wavelength beam combining device illustrated in FIG. 3A.

FIG. 4A is a view schematically illustrating a configuration of a wavelength beam combining device according to an exemplary fourth embodiment of the present disclosure.

FIG. 4B is a view illustrating a first example of a light source device included in the wavelength beam combining device illustrated in FIG. 4A.

FIG. 4C is a view illustrating a second example of a light source device included in the wavelength beam combining device illustrated in FIG. 4A.

FIG. 5 is a view schematically illustrating a configuration of a wavelength beam combining device according to an exemplary fifth embodiment of the present disclosure.

FIG. 6A is a view schematically illustrating a first modified example of the light source device according to the first embodiment.

FIG. 6B is a view schematically illustrating a second modified example of the light source device according to the first embodiment.

FIG. 6C is a view schematically illustrating a third modified example of the light source device according to the first embodiment.

### DETAILED DESCRIPTIONS

A wavelength beam combining device according to embodiments of the present disclosure will be described below in detail with reference to the drawings. Parts having the same reference numerals appearing in the plurality of drawings indicate identical or equivalent parts.

The following disclosure describes embodiments exemplifying the technical ideas of the present invention, but the present invention is not limited to the described embodiments. Furthermore, the description of the dimensions, materials, shapes, relative arrangements, and the like of components are intended to be illustrative rather than limiting the scope of the present invention. The size, positional relationship, and the like of the members illustrated in the drawings may be exaggerated to facilitate understanding and the like. Further, each of the embodiments and each of the modified examples of the present disclosure can be implemented in combination with each other.

### First Embodiment

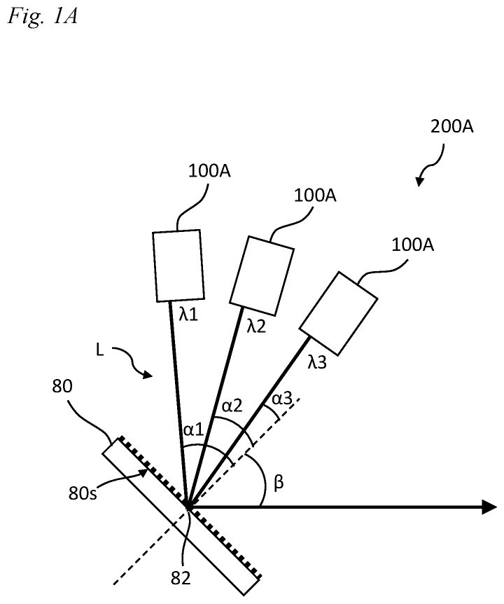

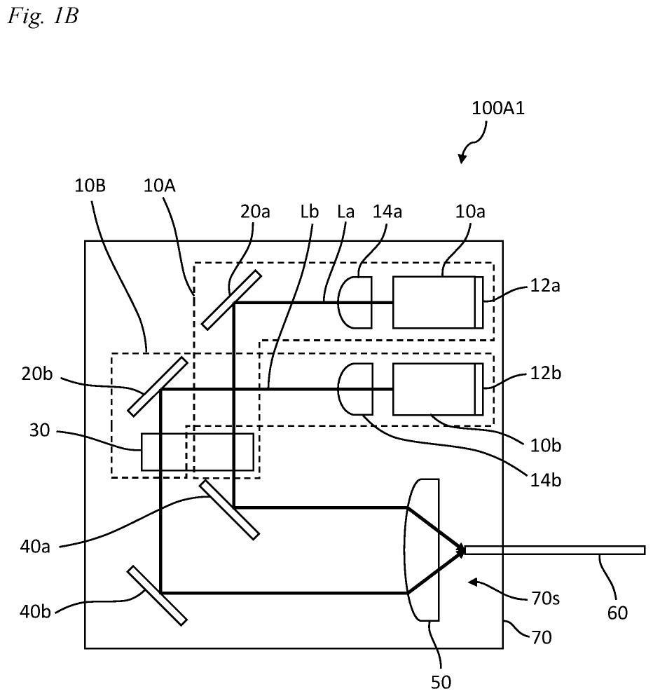

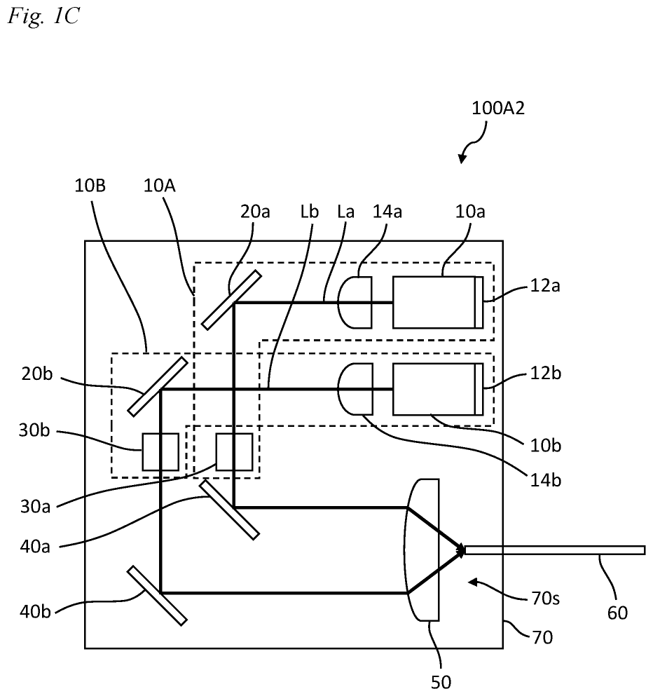

First, a configuration example of the wavelength beam combining device and the light source device according to a first embodiment of the present disclosure will be described with reference to FIGS. 1A to IC. The wavelength beam combining device according to the first embodiment includes a plurality of light source devices, and performs wavelength beam combining of a plurality of laser beams emitted from the plurality of light source devices. The light source device according to the first embodiment may be used without using the WBC technique. For example, the light source device can be used in an exposure device.

### Wavelength Beam Combining Device

FIG. 1A is a view schematically illustrating a configuration of the wavelength beam combining device according to the exemplary first embodiment of the present disclosure. A wavelength beam combining device 200A illustrated in FIG. 1A includes a plurality of light source devices 100A that emit a plurality of laser beams L having mutually different wavelengths, and a diffraction grating 80 that performs wavelength beam combining of the plurality of laser beams L. The plurality of light source devices 100A are disposed in a circular arc in ascending or descending order of the lengths of the wavelengths of the laser beams. The diffraction grating 80 includes a surface 80s, and a plurality of diffraction grooves are periodically provided on the surface 80s. In the example illustrated in FIG. 1A, it is sufficient that the number of the light source devices 100A be two or more. In other examples to be described below, unless otherwise specified, it is sufficient that the number of the light source devices that emit laser beams to be wavelength-beam combined be two or more. In the example illustrated in FIG. 1A, the diffraction grating 80 may be a transmission diffraction grating or may be a reflection diffraction grating. The transmission diffraction grating refers to a diffraction grating in which a metallic reflective film is not formed on the surface 80s, and the reflection diffraction grating refers to a diffraction grating in which a metallic reflective film is formed on the surface 80s. When the diffraction grating 80 is the transmission diffraction grating, reflected diffracted light may be used instead of transmitted diffracted light, as illustrated in FIG. 1A. The transmitted diffracted light may be absorbed by an absorbing member, for example, so as not to become stray light. The transmitted diffracted light may be used instead of the reflected diffracted light.

Of the three light source devices 100A illustrated in FIG. 1A, the light source device 100A at one end emits a laser beam having a wavelength λ1, the light source device 100A in the middle emits a laser beam having a wavelength λ2, and the light source device 100A at the other end emits a laser beam having a wavelength λ3. The wavelength λ1 is longer than the wavelength λ2, and the wavelength λ2 is longer than the wavelength λ3 (that is, λ1>λ2>λ3). The wavelengths λ1, λ2, and λ3 may be, for example, in a range from 200 nm to 1100 nm, preferably in a range from 240 nm to 700 nm, and more preferably in a range from 300 nm to 570 nm. It is assumed that an incident angle of the laser beam L having the wavelength λ1 is defined as α1, an incident angle of the laser beam L having the wavelength 12 is defined as α2, an incident angle of the laser beam L having the wavelength λ3 is defined as α3, and a diffraction angle of the three laser beams Lis B. The incident angle α1 is greater than the incident angle α2, and the incident angle α2 is greater than the incident angle α3 (that is, α1>α2>α3). In the present specification, the wavelength λ1 is also referred to as a “first wavelength,” the wavelength λ2 is also referred to as a “second wavelength,” and the wavelength λ3 is also referred to as a “third wavelength.”

When the incident angles α1 to α3 are simply defined as the incident angle α and the wavelengths λ1 to λ3 are simply defined as the wavelength λ, the incident angle α, the diffraction angle β, and the wavelength λ satisfy the following Formula (1).

$$sin ( α ) + sin ( β ) = N \cdot m \cdot λ \qquad ( 1 )$$

In Formula (1) above, N is the number of diffraction grooves per 1 mm of the diffraction grating 80, and m is a diffraction order. N may be in a range from 1000/mm to 5000/mm, for example.

In the wavelength beam combining device 200A according to the first embodiment, at least one of the plurality of light source devices 100A emits the laser beam L having at least the wavelength λ1 at the time of laser oscillation, and another one of the plurality of light source devices 100A emits the laser beam L having at least the wavelength λ2 at the time of laser oscillation. The plurality of laser beams L including the laser beam L having the wavelength λ1 and the laser beam L having the wavelength λ2 are incident at different angles at a predetermined position 82 of the surface 80s. The diffraction grating 80 designed based on Formula (1) can diffract the plurality of laser beams L and coaxially combine them. As a result, a high-power laser beam can be obtained.

### First Example of Light Source Device

A light source device according to an aspect of the present disclosure includes a first light source unit including a first external resonator formed by a first wavelength selection element and a first resonator mirror, a first light source disposed in the first external resonator and configured to emit a first laser beam during laser oscillation, and a first internal optical path adjusting element that is disposed between the first wavelength selection element and the first light source in the first external resonator and is configured to allow the first laser beam to be incident on the first wavelength selection element. The light source device includes a second light source unit including a second external resonator formed by the first wavelength selection element and a second resonator mirror, a second light source disposed in the second external resonator and configured to emit a second laser beam during laser oscillation, and a second internal optical path adjusting element that is disposed between the first wavelength selection element and the second light source in the second external resonator and is configured to allow the second laser beam to be incident on the first wavelength selection element. The light source device includes a first external optical path adjusting element that is disposed outside the first external resonator and is configured to allow the first laser beam to be incident in a predetermined direction, and a second external optical path adjusting element that is disposed outside the second external resonator and is configured to allow the second laser beam to be incident in a predetermined direction.

In the light source device according to the embodiment of the present disclosure configured as described above, a high-power laser beam can be obtained. In other words, the output of the wavelength beam combining device including the above-described light source device can be increased.

FIG. 1B is a view illustrating a first example of the light source device 100A included in the wavelength beam combining device 200A illustrated in FIG. 1A. A light source device 100A1 illustrated in FIG. 1B includes a first light source unit 10A, a second light source unit 10B, a first outer mirror 40a, a second outer mirror 40b, a condensing lens 50, an optical fiber 60, and a support base 70 having a surface 70s that supports these components. In the example illustrated in FIG. 1B, the number of the light source units 10A and 10B is two, but the configuration is not limited to this number and may be three or more. The number of the outer mirrors 40a and 40b is the same as the number of the light source units 10A and 10B.

The first light source unit 10A emits a first laser beam La, and the second light source unit 10B emits a second laser beam Lb. The wavelength of the second laser beam Lb is the same as the wavelength of the first laser beam La. The first outer mirror 40a reflects the first laser beam La to allow the first laser beam La to be incident on the condensing lens 50. Similarly, the second outer mirror 40b reflects the second laser beam Lb to allow the second laser beam Lb to be incident on the condensing lens 50. The condensing lens 50 condenses the first laser beam La adjusted by the first outer mirror 40a and the second laser beam Lb adjusted by the second outer mirror 40b and combines them in the optical fiber 60. The optical fiber 60 guides the first laser beam La and the second laser beam Lb. As a result, a high-power laser beam is emitted from the light source device 100A1. The greater the number of the light source units 10A and 10B, the more the power of the combined beam increases.

Each of the components of the light source device 100A1 will be described in detail below.

### Light Source Unit 10A, 10B

The first light source unit 10A includes a first external resonator formed by a wavelength selection element 30 and a first resonator mirror 12a, and a first light source 10a, a first collimating lens 14a, and a first inner mirror 20a that are disposed in the first external resonator. The first light source 10a, the first collimating lens 14a, and the first inner mirror 20a are disposed in this order from the side closer to the first resonator mirror 12a.

The first light source 10a emits the first laser beam La during the laser oscillation. The first light source 10a can include a semiconductor laser element, for example. The semiconductor laser element includes two mirrors facing each other and with a gain medium positioned between the two mirrors, and emits the first laser beam La from an emission surface of one of the mirrors. The emission surface may be provided with an anti-reflection coating instead of being the mirror. The first resonator mirror 12a can be the other mirror included in the semiconductor laser element, for example. The semiconductor laser element may be a transverse multimode laser. A ridge width of the semiconductor laser element may be in a range from 20 μm to 100 μm, for example. When the semiconductor laser element is an end surface emitting type and the emission surface has a rectangular shape elongated in one direction, the first laser beam La spreads relatively quickly in the fast-axis direction and spreads relatively slowly in the slow-axis direction as it travels. When the emission surface has a rectangular shape elongated in a direction parallel to the surface 70s of the support base 70, the fast-axis direction is perpendicular to the surface 70s, and the slow-axis direction is parallel to the surface 70s. Alternatively, the first light source 10a may include a semiconductor laser amplifier, or may be a master oscillator power amplifier (MOPA) laser element. In this way, the output of each of the light sources can be increased, so that the power of the laser beam extracted from the light source device 100A1 can be further increased.

The first collimating lens 14a is disposed between the first light source 10a and the first inner mirror 20a, and collimates the first laser beam La in the fast-axis direction and the slow-axis direction. In the present specification, “collimating” refers to not only allowing the laser beams to be parallel light but also to reducing the spread angle of the laser beams. The focal point of the first collimating lens 14a is positioned substantially at the center of an active layer of the above-described emission surface. The first collimating lens 14a may be a single lens, or may include a fast-axis collimating lens and a slow-axis collimating lens. The fast-axis collimating lens and the slow-axis collimating lens may be cylindrical lenses, for example. The first inner mirror 20a is disposed between the first light source 10a and the wavelength selection element 30 in the first external resonator, and reflects the first laser beam La to allow the first laser beam La to be incident on the wavelength selection element 30. The first inner mirror 20a corrects a deviation of the optical axis of the first laser beam La in the direction parallel to and in the direction perpendicular to the surface 70s of the support base 70, and allows the first laser beam La to be perpendicularly incident on the wavelength selection element 30.

The second light source unit 10B includes a second external resonator formed by the wavelength selection element 30 and a second resonator mirror 12b, and a second light source 10b, a second collimating lens 14b, and a second inner mirror 20b that are disposed in the second external resonator. The second light source 10b, the second collimating lens 14b, and the second inner mirror 20b are disposed in this order from the side closer to the second resonator mirror 12b.

The second light source 10b emits the second laser beam Lb during the laser oscillation. The wavelength of the second laser beam Lb is the same as the wavelength of the first laser beam La. The second light source 10b may have the same structure as the first light source 10a, for example. The second collimating lens 14b is disposed between the second optical source 10b and the second inner mirror 20b, and collimates the second laser beam Lb in the fast-axis direction and the slow-axis direction. The second collimating lens 14b may have the structure same as or similar to that of the first collimating lens 14a, for example. The second inner mirror 20b is disposed between the second optical source 10b and the wavelength selection element 30 in the second external resonator, and reflects the second laser beam Lb to allow the second laser beam Lb to be incident on the wavelength selection element 30. The second inner mirror 20b corrects a deviation of the optical axis of the second laser beam Lb in the direction parallel to and in the direction perpendicular to the surface 70s of the support base 70, and allows the second laser beam Lb to be perpendicularly incident on the wavelength selection element 30.

By selectively reflecting light of a specific wavelength, the wavelength selection element 30 narrows the wavelength of the first laser beam La during the laser oscillation in the first external resonator and the wavelength of the second laser beam Lb during the laser oscillation in the second external resonator. In this way, the light having the wavelength selected by the wavelength selection element 30 resonates in the first external resonator and the second external resonator. Thus, the first light source unit 10A and the second light source unit 10B can stably emit the first laser beam La and the second laser beam Lb having constant wavelengths, regardless of a temperature dependency of the oscillation wavelengths, and manufacturing variations of the first light source 10a and the second light source 10b. By using the wavelength selection element 30 common to the first light source unit 10A and the second light source unit 10B, the cost of the components can be reduced.

The wavelength selection element 30 may be, for example, a volume holographic grating (VHG) having a periodic refractive index structure. The VHG selectively reflects the light of the specific wavelength that is perpendicularly incident thereon. In the present specification, the wavelength selection element 30 is also referred to as a “first wavelength selection element,” and the VHG used as the wavelength selection element 30 is also referred to as a “first volume holographic grating (a first VHG).” A bandwidth that can be selected by the wavelength selection element 30 is, for example, in a range from 0.01 nm to 0.5 nm, preferably in a range from 0.01 nm to 0.25 nm, and more preferably in a range from 0.01 nm to 0.05 nm. The VHG is preferable, for example, when the wavelength is set in advance of the light source device to be used, as in the case of WBC. It is sufficient that the VHG be fixed so that the desired wavelength is selected. Further, the VHG is stable because there is no need to move the VHG once it is fixed to the support base 70.

In contrast to the light source device 100A1, in a configuration in which the laser beams La and Lb emitted from the light sources 10a and 10b and passing through the collimating lenses 14a and 14b are directly incident on the wavelength selection element 30 without passing through the inner mirrors 20a and 20b, there is a possibility that a desired external resonance may not be obtained due to misalignment when mounting these members. For example, the light sources 10a and 10b may be bonded to the support base 70 via an inorganic bonding member. When the inorganic bonding member is a solder material, for example, it is necessary to adjust the positions and the orientations of the light sources 10a and 10b during a period in which the solder material is heated and melted. Subsequently, the solder material is naturally cooled, and the light sources 10a and 10b are thus bonded to the support base 70. Although the laser beams La and Lb are illustrated as being emitted from the light sources 10a and 10b in the same direction in FIG. 1B, there is a possibility that the laser beams La and Lb are not emitted from the light sources 10a and 10b in the same direction, depending on a state of the bonding of the light sources 10a and 10b using the inorganic bonding member. In the above-described configuration, when the wavelength selection element 30 is the VHG, it is not easy to allow the laser beams La and Lb traveling in different directions to be perpendicularly incident on the wavelength selection element 30.

In contrast to this, in the light source device 100A1, for example, active alignment is performed in which the first laser beam La is aligned by adjusting the position and orientation of the first inner mirror 20a while allowing the first laser beam La to be emitted from the light source 10a, and in which the second laser beam Lb is aligned by adjusting the position and orientation of the second inner mirror 20b while allowing the second laser beam Lb to be emitted from the light source 10b. Through the active alignment, the laser beams La and Lb reflected by the inner mirrors 20a and 20b can be allowed to be perpendicularly incident on the wavelength selection element 30. In other words, the first inner mirror 20a is disposed so that the first laser beam La is perpendicularly incident on the wavelength selection element 30, and the second inner mirror 20b is disposed so that the second laser beam Lb is perpendicularly incident on the wavelength selection element 30. As a result, the wavelengths of the laser beams La and Lb can be stably maintained at the same wavelength.

The wavelength selection element 30 may be a transmission or reflection diffraction grating having a plurality of diffraction grooves. In this case, the laser beams La and Lb do not need to be perpendicularly incident on the wavelength selection element 30, and the incident angle and the diffraction angle of the laser beams La and Lb are determined by Formula (1).

### Outer Mirrors 40a and 40b, Condensing Lens 50, and Optical Fiber 60

The first outer mirror 40a is disposed outside the first external resonator and allows the first laser beam La that has passed through the wavelength selection element 30 to be incident in a predetermined direction. Similarly, the second outer mirror 40b is disposed outside the second external resonator, and allows the second laser beam Lb that has passed through the wavelength selection element 30 to be incident in a predetermined direction.

In contrast to the light source device 100A1, in a configuration in which the laser beams La and Lb that have passed through the wavelength selection element 30 are directly incident on the condensing lens 50 without being reflected by the outer mirrors 40a and 40b, there is a possibility that the optical axes of the first laser beam La and the second laser beam Lb that have passed through the wavelength selection element 30 may become deviated from each other. This is because the first inner mirror 20a and the second inner mirror 20b correct a misalignment of the first light source 10a and the second light source 10b at a time of mounting. For example, the wavelength selection element 30 and the condensing lens 50 may be bonded to the support base 70 via an inorganic bonding member, for example. Depending on a bonding state of the wavelength selection element 30 and the condensing lens 50 via the inorganic bonding member, it is not easy to allow the laser beams La and Lb that have passed through the wavelength selection element 30 to be incident in a direction parallel to the optical axis of the condensing lens 50.

In contrast, in the light source device 100A1, for example, active alignment is performed in which the first laser beam La is aligned by adjusting the position and orientation of the first outer mirror 40a while allowing the first light source unit 10A to emit the first laser beam La, and the second laser beam Lb is aligned by adjusting the position and orientation of the second inner mirror 20b while the second light source unit 10B is allowed to emit the second laser beam Lb. Through the active alignment, the laser beams La and Lb reflected by the outer mirrors 40a and 40b can be allowed to be incident in the predetermined direction. In the example illustrated in FIG. 1B, the predetermined direction is a direction parallel to the optical axis of the condensing lens 50. As a result, the laser beams La and Lb can be effectively combined in the optical fiber 60 using the condensing lens 50. The condensing lens 50 may be a single lens or may include a fast-axis condensing lens and a slow-axis condensing lens. The fast-axis condensing lens and the slow-axis condensing lens may be cylindrical lenses, for example. The laser beams La and Lb are condensed by the condensing lens 50 and combined in the optical fiber. The optical fiber 60 guides the laser beams La and Lb and outputs a combined beam.

In the example illustrated in FIG. 1B, the predetermined direction is opposite to the direction in which the laser beams La and Lb are emitted from the light sources 10a and 10b. In this case, because the condensing lens 50 and the optical fiber 60 can be disposed on the same side as the first light source 10a and the second light source 10b, the light source device 100A1 can be reduced in size. However, the predetermined direction may be the same direction as the direction in which the laser beams La and Lb are emitted from the light sources 10a and 10b, or may be other directions.

### Support Base 70

The surface 70s of the support base 70 directly or indirectly supports the light source 10a, the collimating lens 14a, and the inner mirror 20a. The light source 10a, the collimating lens 14a, and the inner mirror 20a are directly or indirectly supported in a first plane (i.e., a region of the upper surface), with respect to the lower surface of the support base 70 as a reference height. The surface 70s of the support base 70 directly or indirectly supports the light source 10b, the collimating lens 14b, and the inner mirror 20b. The light source 10b, the collimating lens 14b, and the inner mirror 20b are directly or indirectly supported in a second plane (i.e., an region of the upper surface), with respect to the lower surface of the support base 70 as the reference height. The height of the first plane and the height of the second plane may be the same or may be different from each other. That is, the heights of the optical axes of the first laser beam and the second laser beam can be adjusted as necessary. A method of adjusting the height of the optical axis may be performed using a known method.

Further, the surface 70s of the support base 70 directly or indirectly supports the wavelength selection element 30, the outer mirrors 40a and 40b, the condensing lens 50, and the optical fiber 60. The outer mirrors 40a and 40b, the condensing lens 50, and the optical fiber 60 are directly or indirectly supported at the same height in a third plane (i.e., a region of the upper surface), with respect to the lower surface of the support base 70 as a reference height. In the example illustrated in FIG. 1B, the first plane, the second plane, and the third plane are positioned in the same plane, but need not necessarily be positioned in the same plane.

The support base 70 is preferably formed of a material that effectively conducts heat generated from the light sources 10a and 10b during laser oscillation and heat generated in components receiving the laser beams La and Lb, to the outside of the light source device 100A1. The support base 70 may be formed of a ceramic selected from the group consisting of AlN, SiN, SiC, and alumina, for example. Alternatively, the support base 70 may be formed of at least one metal material selected from the group consisting of Cu, Al, and Ag, for example. That is, the material of the support base 70 may be a single metal or may be an alloy. The alloy may be CuW or CuMo, for example. The support base 70 may be formed of a metal matrix composite material having diamond particles dispersed in at least the one metal material selected from the group consisting of Cu, Al, and Ag, for example.

### Other Components

As other components, the light source device 100A1 may include a cap that seals the light source units 10A and 10B, the outer mirrors 40a and 40b, and the condensing lens 50. This seal is preferably a hermetic seal. As a result of the hermetic sealing, the collection of dust at the emission surfaces of the light sources 10a and 10b is reduced, and thus failure of the light sources 10a and 10b is less likely to occur. The effect of the hermetic seal increases as the wavelength of the laser beams emitted from the light sources 10a and 10b becomes shorter.

As another constituent element, in the light source device 100A1, the positions of the light source 10a and the first collimating lens 14a, or the positions the light source 10b and the second collimating lens 14b may be adjusted so that a resonator length of the first external resonator and a resonator length of the second external resonator are the same as each other. Equalizing the resonator lengths can reduce a shift in the wavelength selected by the wavelength selection element 30.

Up to this point, FIG. 1B has been used to describe the light source device 100A1, and the wavelength beam combining device illustrated in FIG. 1A may be configured by a plurality of light source devices 100A1. At this time, the wavelength selection elements 30 mounted on the light source devices 100A1 select different wavelengths for each of the light source devices 100A1. In other words, by appropriately selecting the wavelength selection elements 30, for example, the first wavelength, the second wavelength, the third wavelength, or other wavelengths in FIG. 1A can be selectively extracted. The same applies to any of the light source devices to be described below.

### Second Example of Light Source Device

A light source device according to an aspect of the present disclosure includes a first light source unit including a first external resonator formed by a first wavelength selection element and a first resonator mirror, a first light source disposed in the first external resonator and configured to emit a first laser beam during laser oscillation, and a first internal optical path adjusting element that is disposed between the first wavelength selection element and the first light source in the first external resonator and is configured to allow the first laser beam to be incident on the first wavelength selection element. The light source device includes a second light source unit including a second external resonator formed by a second wavelength selection element and a second resonator mirror, a second light source disposed in the second external resonator and configured to emit a second laser beam during laser oscillation, and a second internal optical path adjusting element that is disposed between the second wavelength selection element and the second light source in the second external resonator and is configured to allow the second laser beam to be incident on the second wavelength selection element. The light source device includes a first external optical path adjusting element that is disposed outside the first external resonator and is configured to allow the first laser beam to be incident in a predetermined direction, and a second external optical path adjusting element that is disposed outside the second external resonator and is configured to allow the second laser beam to be incident in a predetermined direction.

In the light source device according to the embodiment of the present disclosure configured as described above, a high-power laser beam can be obtained.

FIG. 1C is a view illustrating a second example of a light source device 100A included in the wavelength beam combining device 200A illustrated in FIG. 1A. The light source device 100A2 illustrated in FIG. 1C is different from the light source device 100A1 illustrated in FIG. 1B in that the light source device 100A2 includes a first wavelength selection element 30a for selecting the wavelength of the laser beam La and a second wavelength selection element 30b for selecting the wavelength of the laser beam Lb, instead of the wavelength selection element 30 common to the first light source unit 10A and the second light source unit 10B. The first wavelength selection element 30a and the second wavelength selection element 30b may have the same structure as the wavelength selection element 30. Thus, the first laser beam La and the second laser beam Lb can be externally resonated at respectively desired wavelengths. When the identical wavelength selection elements are used as the first wavelength selection element 30a and the second wavelength selection element 30b, selectable wavelength bands are aligned, so that the wavelengths of the laser beams La and Lb can be stably maintained at the same wavelength. The first external resonator included in the first light source unit 10A is formed by the first resonator mirror 12a and the first wavelength selection element 30a. The second external resonator included in the second light source unit 10B is formed by the second resonator mirror 12b and the second wavelength selection element 30b. The first inner mirror 20a is disposed between the first wavelength selection element 30a and the first light source 10a in the first external resonator. The second inner mirror 20b is disposed between the second wavelength selection element 30b and the second light source 10b in the second external resonator.

In the light source device 100A2, the first wavelength selection element 30a and the second wavelength selection element 30b can be respectively disposed in accordance with an inclined state after the first light source 10a and the second light source 10b are bonded to the support base 70. The first wavelength selection element 30a may be a first volume holographic grating, for example, and the second wavelength selection element 30b may be a second volume holographic grating, for example. In this case, it is easy to dispose the first inner mirror 20a so that the laser beam La is perpendicularly incident on the first wavelength selection element 30a and to dispose the second inner mirror 20b so that the laser beam Lb is perpendicularly incident on the second wavelength selection element 30b.

As described above, in the light source devices 100A1 and 100A2 according to the first embodiment, the optical paths of the laser beams La and Lb can be adjusted by the inner mirrors 20a and 20b. When the wavelength selection elements 30, 30a, and 30b are the VHG, the wavelengths of the laser beams La, Lb can be narrowed in a stable manner by allowing the laser beams La, Lb to be perpendicularly incident on the wavelength selection elements 30, 30a, and 30b using the inner mirrors 20a, 20b.

Furthermore, in the light source devices 100A1 and 100A2 according to the first embodiment, the optical paths of the laser beams La and Lb can be adjusted by the outer mirrors 40a and 40b. By using the outer mirrors 40a and 40b to allow the traveling directions of the laser beams La and Lb to be parallel to the optical axis of the condensing lens 50, the laser beams La and Lb can be effectively combined in the optical fiber 60 by the condensing lens 50. As a result, a high-power laser beam can be obtained in the light source devices 100A1 and 100A2.

### Second Embodiment

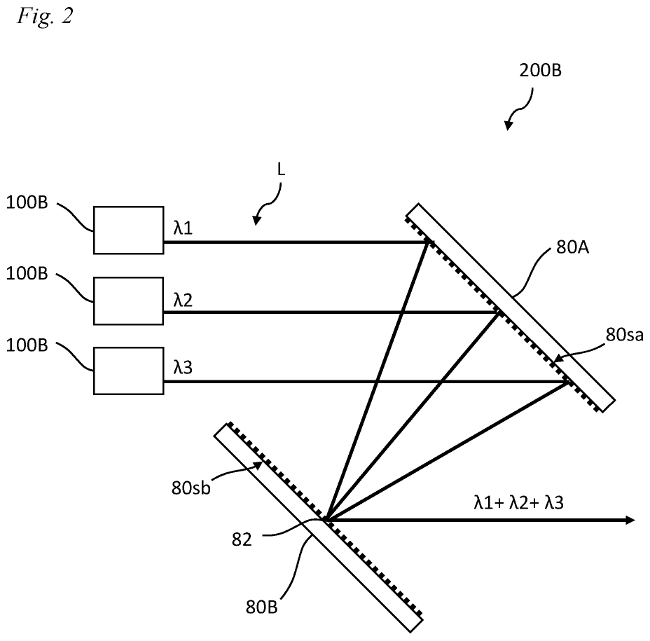

Next, a configuration example of a wavelength beam combining device including a plurality of light source devices according to a second embodiment of the present disclosure will be described with reference to FIG. 2.

### Wavelength Beam Combining Device

FIG. 2 is a view schematically illustrating the configuration of the wavelength beam combining device according to the exemplary second embodiment of the present disclosure. A wavelength beam combining device 200B illustrated in FIG. 2 includes a plurality of light source devices 100B that emit laser beams L having mutually different wavelengths, and a pair of diffraction gratings 80A and 80B (a first diffraction grating 80A and a second diffraction grating 80B) that coaxially combine the plurality of laser beams L. Both the first diffraction grating 80A and the second diffraction grating 80B are preferably transmission diffraction gratings. In this way, even when an intensity of the laser beam emitted from each of the plurality of light source devices 100B is increased, damage to the diffraction gratings can be suppressed because there is no metallic reflective film that absorbs some of the laser beams. Further, when both the first diffraction grating 80A and the second diffraction grating 80B are the transmission diffraction gratings, the transmission diffraction gratings need not necessarily use the transmitted diffracted light, and may use the reflected diffracted light, as illustrated in FIG. 2A. The transmission diffraction grating may be disposed such that the laser beams are incident on the surface having the diffraction grooves. The first diffraction grating 80A and the second diffraction grating 80B may be disposed such that the surfaces having the diffraction grooves face each other.

The plurality of light source devices 100B are disposed in descending or ascending order of the wavelengths of the laser beams L. A direction in which the plurality of light source devices 100B are disposed is a direction intersecting the emission direction of the laser beams L, more specifically, a direction orthogonal to the emission direction. The plurality of light source devices 100B may be disposed in a row. Thus, the light source devices 100B can be easily disposed, and a mounting space of the light source devices 100B can be reduced. The first diffraction grating 80A and the second diffraction grating 80B are disposed in parallel to each other. The first diffraction grating 80A has a first surface 80sa, and the plurality of diffraction grooves are periodically provided on the first surface 80sa. Similarly, the second diffraction grating 80B has a second surface 80sb, and the plurality of diffraction grooves are periodically provided on the second surface 80sb. The first surface 80sa and the second surface 80sb face each other. The first diffraction grating 80A and the second diffraction grating 80B have the same structure and the same number of diffraction grooves, for example.

For example, the first diffraction grating 80A is configured to diffract the plurality of laser beams L, which are incident in parallel at the same incident angle, at different diffraction angles according to the wavelength thereof, and to allow the laser beams L to be incident at the predetermined position 82 of the second diffraction grating 80B facing the first diffraction grating 80A. The second diffraction grating 80B having the same structure as that of the first diffraction grating 80A is configured such that the light diffracted by the first diffraction grating 80A is incident at the different incident angles according to the wavelength and emit the light diffracted by the second diffraction grating 80B at the same diffraction angle as the light incident on the first diffraction grating 80A. In this way, the pair of diffraction gratings 80A and 80B can form the coaxial wavelength-combined beam.

As described above, in the wavelength beam combining device 200B according to the second embodiment, one of the plurality of light source devices 100B emits at least the laser beam having the wavelength λ1 at the time of laser oscillation, and another one of the plurality of light source devices 100B emits at least the laser beam having the wavelength λ2 at the time of laser oscillation. The first diffraction grating 80A diffracts the plurality of laser beams L including the laser beam having the wavelength λ1 and the laser beam having the wavelength λ2 that are incident at the same angle, and allows the diffracted laser beams L to be incident at the predetermined position 82 of the second diffraction grating 80B at the different angles according to the wavelength. The second diffraction grating 80B diffracts the plurality of laser beams L diffracted by the first diffraction grating 80A, to form the wavelength-combined beam. As a result, a high-power laser beam can be obtained.

### Third Embodiment

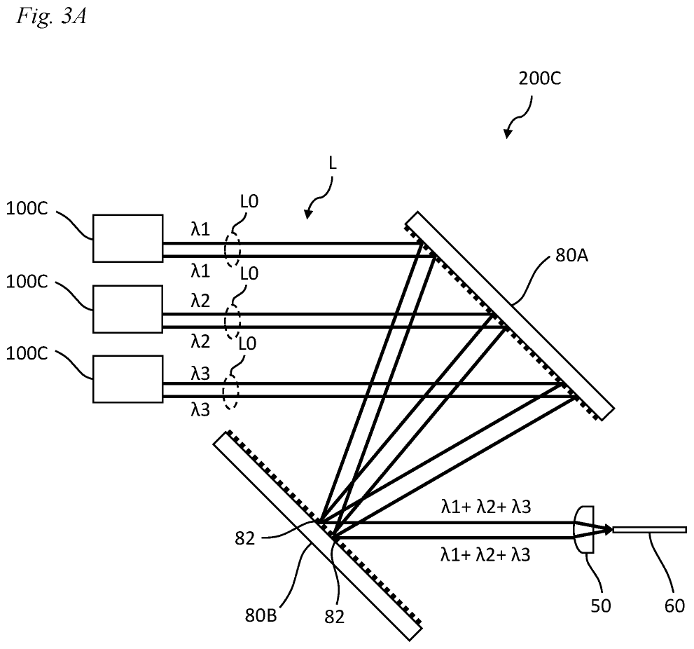

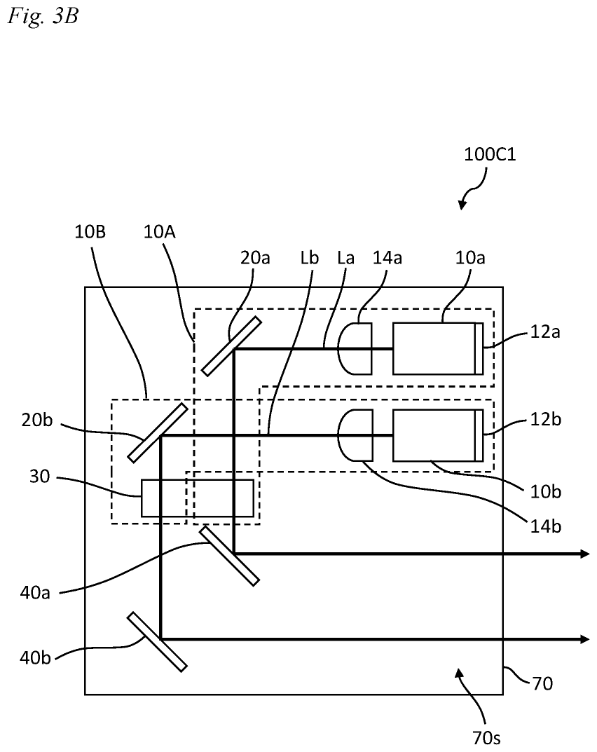

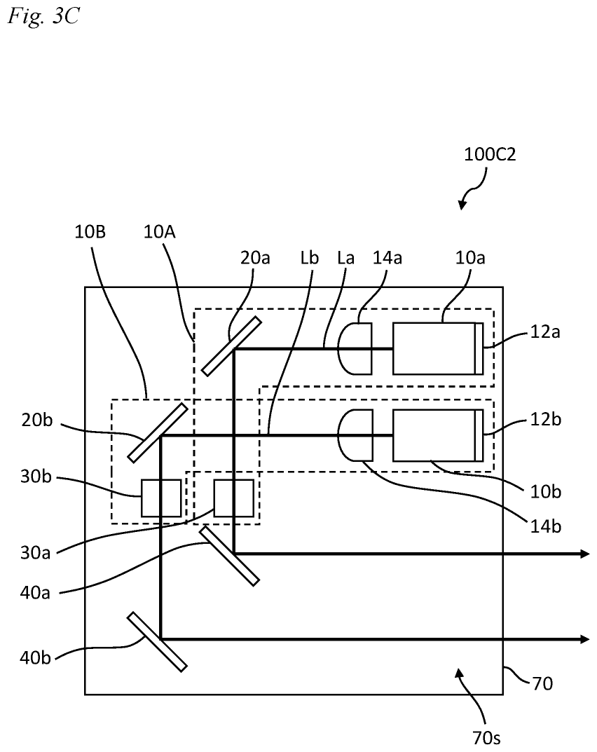

Next, a configuration example of a wavelength beam combining device including a plurality of light source devices according to a third embodiment of the present disclosure, and a configuration example of the light source device according to the third embodiment of the present disclosure will be described with reference to FIGS. 3A to 3C.

### Wavelength Beam Combining Device

FIG. 3A is a view schematically illustrating a configuration of a wavelength beam combining device according to the exemplary third embodiment of the present disclosure. A wavelength beam combining device 200C illustrated in FIG. 3A includes a plurality of light source devices 100C, the pair of diffraction gratings 80A and 80B, the condensing lens 50, and the optical fiber 60.

The plurality of light source devices 100C are disposed in ascending or descending order of the wavelengths of the laser beams L and emit the plurality of laser beams L. Each of the plurality of light source devices 100C emits two or more laser beams L0 having the same wavelength in parallel to each other. The plurality of laser beams L include the two or more laser beams L0 having the same wavelength emitted from each of the light source devices 100C.

The wavelength of the two or more laser beams L0 emitted from a given one of the plurality of light source devices 100C is different from the wavelength of the two or more laser beams L0 emitted from another given one of the light source devices 100C. The number of the laser beams L0 emitted from the given one of the light source devices 100C is the same as the number of the laser beams L0 emitted from the other given one of the light source devices 100C. In the example illustrated in FIG. 3A, the number of the laser beams L0 emitted from each of the light source devices 100C is two, but is not limited to two, and may be three or more.

The first diffraction grating 80A and the second diffraction grating 80B are the same as described above. The first diffraction grating 80A diffracts a plurality of laser beams having different wavelengths that are incident at the same angle, among the plurality of laser beams L, and allows the diffracted laser beams to be incident at the predetermined position 82 of the second diffraction grating 80B, at different angles according to the wavelength. Because the two or more laser beams having the same wavelength are emitted from each of the light source devices 100C, the number of the predetermined positions 82 is the same as the number of the laser beams emitted from each of the light source devices 100C. The second diffraction grating 80B diffracts the plurality of laser beams having the different wavelengths diffracted by the first diffraction grating 80A, to form two or more wavelength-combined beams. The number of wavelength-combined beams is the same as the number of the laser beams emitted from each of the light source devices 100C, as the same as the number of the predetermined positions 82. The condensing lens 50 combines the two or more wavelength-combined beams formed by the second diffraction grating 80B. The optical fiber 60 guides the combined two or more wavelength-combined beams. As a result, a high-power laser beam can be obtained. At this time, a difference between the wavelength λ1 and the wavelength λ3 is preferably in a range from 0.1 nm to 30 nm. Further, a difference between the wavelength λ1 and the wavelength λ2, and a difference between the wavelength λ2 and the wavelength λ3 are in a range from 0.05 nm to 15 nm. In this way, the influence of a wavelength dispersion of the condensing lens 50 can be reduced even when using the condensing lens 50, and the light can be condensed at substantially the same position. Thus, a combining efficiency in the optical fiber 60 can be improved.

### First Example and Second Example of Light Source Device

FIGS. 3B and 3C respectively illustrate first and second examples of the light source device 100C included in the wavelength beam combining device 200C illustrated in FIG. 3A. Light source devices 100C1 and 100C2 illustrated in FIGS. 3B and 3C are different from the light source device 100A1 illustrated in FIG. 1B in that the light source devices 100C1 and 100C2 do not include the condensing lens 50 and the optical fiber 60. The light source devices 100C1 and 100C2 emit the first laser beam La that is emitted from the first light source unit 10A and reflected in the predetermined direction by the first outer mirror 40a, and the second laser beam Lb that is emitted from the second light source unit 10B and reflected in the predetermined direction by the second outer mirror 40b. The laser beams La and Lb emitted from the light source devices 100C1 and 100C2 correspond to the two or more laser beams L0 emitted from each of the light source devices 100C illustrated in FIG. 3A. The number of the laser beams La and Lb emitted from the light source devices 100C1 and 100C2 is equal to the number of the light source units 10A and 10B.

In the wavelength beam combining device 200C according to the third embodiment, the two or more wavelength-combined beams formed by the pair of diffraction gratings 80A and 80B are incident in the predetermined direction, in a manner same as or similar to the two or more laser beams L0 emitted from each of the light source devices 100C. Therefore, by disposing the condensing lens 50 so that the optical axis of the condensing lens 50 is parallel to the predetermined direction, the two or more wavelength-combined beams can be effectively combined by the condensing lens 50. As a result, a high-power laser beam can be obtained.

Furthermore, in the wavelength beam combining device 200C according to the third embodiment, unlike the wavelength beam combining device 200B according to the second embodiment, each of the light source devices 100C need not necessarily include the condensing lens 50 and the optical fiber 60. Because the number of the condensing lenses 50 is one and the number of the optical fibers 60 is one in the wavelength beam combining device 200C, the cost of the components can be reduced.

### Fourth Embodiment

### Wavelength Beam Combining Device

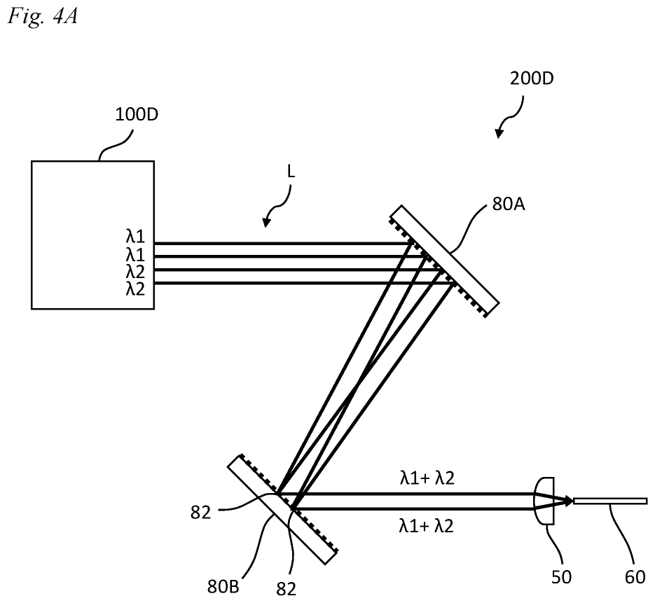

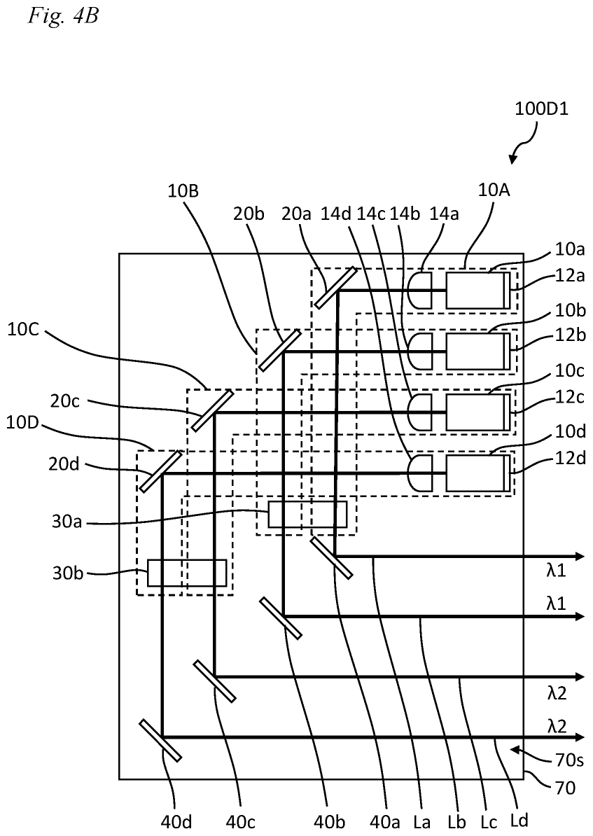

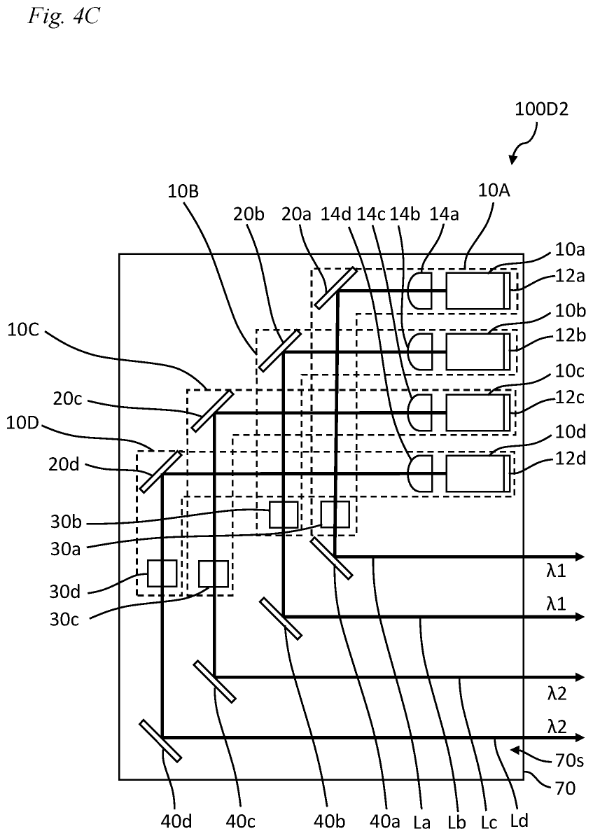

Next, a configuration example of a wavelength beam combining device including a plurality of light source devices according to a fourth embodiment of the present disclosure and a configuration example of the light source device according to the fourth embodiment of the present disclosure will be described with reference to FIGS. 4A to 4C.

FIG. 4A is a view schematically illustrating the configuration of the wavelength beam combining device according to the exemplary fourth embodiment of the present disclosure. A wavelength beam combining device 200D illustrated in FIG. 4A includes a light source device 100D, the pair of diffraction gratings 80A and 80B, the condensing lens 50, and the optical fiber 60. The light source device 100D emits the plurality of laser beams L in parallel to each other. The plurality of laser beams L include two or more laser beams of a certain wavelength and two or more laser beams of another wavelength adjacent to the laser beams of the certain wavelength. The plurality of laser beams L may further include two or more laser beams of yet another wavelength adjacent to the two or more laser beams of another wavelength and on the opposite side from the two or more laser beams of the certain wavelength. Among the plurality of laser beams L, the number of the two or more laser beams of any given wavelength is the same as the number of two or more of the laser beams of any of the other wavelengths. In the example illustrated in FIG. 4A, the light source device 100D emits two laser beams having the wavelength λ1 and two laser beams having the wavelength λ2, but the number of the laser beams having the wavelength λ1 may be three or more instead of two, and the number of the laser beams having the wavelength λ2 may be three or more instead of two.

The wavelength beam combining device 200D illustrated in FIG. 4A corresponds to a structure obtained by modifying the wavelength beam combining device 200C illustrated in FIG. 3A as follows. In other words, the light source device 100D has a structure in which the light source device 100C that emits the two or more laser beams having the wavelength λ1 and the light source device 100C that emits the two or more laser beams having the wavelength λ2 are integrally formed.

The plurality of laser beams L emitted from the wavelength beam combining device 200D are combined in the optical fiber 60 by the condensing lens 50 via the pair of diffraction gratings 80A and 80B, and are subsequently guided by the optical fiber 60. The manner in which the plurality of laser beams L illustrated in FIG. 4A travel is the same as the manner in which the plurality of laser beams L illustrated in FIG. 3A travel, except that the two or more laser beams L0 having the wavelength λ3 illustrated in FIG. 3A are not taken into consideration.

In the wavelength beam combining device 200D according to the fourth embodiment, unlike the wavelength beam combining device 200C according to the third embodiment, the two or more laser beams having the certain wavelength and the two or more laser beams having another wavelength can be emitted by the single light source device 100D, instead of the plurality of light source devices 100D. Thus, the light source device 100D is easily disposed. The wavelength λ1 is longer than the wavelength λ2. The difference between the wavelength λ1 and the wavelength λ2 is in a range from 0.05 nm to 15 nm, and is preferably in a range from 1 nm to 5 nm. In this way, the influence of the wavelength dispersion by the condensing lens 50 can be reduced even when using the condensing lens 50, and the light can be condensed at substantially the same position. Thus, the combining efficiency in the optical fiber 60 can be improved.

### First Example of Light Source Device

FIG. 4B is a view illustrating a first example of the light source device 100D included in the wavelength beam combining device 200D illustrated in FIG. 4A. A light source device 100D1 illustrated in FIG. 4B is different from the light source device 100C1 illustrated in FIG. 3B in that the light source device 100D1 further includes a third light source unit 10C, a fourth light source unit 10D, a third outer mirror 40c, and a fourth outer mirror 40d. The support base 70 supports the light source units 10A to 10D and the outer mirrors 40a to 40d. The first wavelength selection element 30a illustrated in FIG. 4B corresponds to the wavelength selection element 30 illustrated in FIG. 3B. The first wavelength selection element 30a stably narrows the wavelengths of the laser beams La and Lb to λ1, the laser beams La and Lb being perpendicularly incident on the first wavelength selection element 30a. The first wavelength selection element 30a may be the first VHG, for example.

The third light source unit 10C includes a third external resonator formed by the second wavelength selection element 30b and a third resonator mirror 12c, and includes a third light source 10c, a third collimating lens 14c, and a third inner mirror 20c that are disposed in the third external resonator. The third light source 10c, the third collimating lens 14c, and the third inner mirror 20c are disposed in this order from the side closer to the third resonator mirror 12c.

The third light source 10c emits a third laser beam Lc during the laser oscillation. The third light source 10c may have the same structure as the first light source 10a, for example. The third collimating lens 14c is disposed between the third light source 10c and the third inner mirror 20c, and collimates the third laser beam Lc. The third collimating lens 14c may have the structure same as or similar to that of the first collimating lens 14a, for example. The third inner mirror 20c is disposed between the third light source 10c and the second wavelength selection element 30b in the third external resonator, and reflects the third laser beam Lc to allow the third laser beam Lc to be incident on the second wavelength selection element 30b.

The fourth light source unit 10D includes a fourth external resonator formed by the second wavelength selection element 30b and a fourth resonator mirror 12d, and includes a fourth light source 10d, a fourth collimating lens 14d, and a fourth inner mirror 20d that are disposed in the fourth external resonator. The fourth light source 10d, the fourth collimating lens 14d, and the fourth inner mirror 20d are disposed in this order from the side closer to the fourth resonator mirror 12d.

The fourth light source 10d emits a fourth laser beam Ld during the laser oscillation. The fourth light source 10d may have the same structure as the first light source 10a, for example. The fourth collimating lens 14d is disposed between the fourth light source 10d and the fourth inner mirror 20d, and collimates the fourth laser beam Ld. The fourth collimating lens 14d may have the structure same as or similar to that of the first collimating lens 14a, for example. The fourth inner mirror 20d is disposed between the fourth light source 10d and the second wavelength selection element 30b in the fourth external resonator, and reflects the fourth laser beam Ld to allow the fourth laser beam Ld to be incident on the second wavelength selection element 30b.

The second wavelength selection element 30b selectively reflects a wavelength different from that of the first wavelength selection element 30a. The second wavelength selection element 30b may be a second VHG, for example. In this case, the third inner mirror 20c is disposed so that the third laser beam Lc is perpendicularly incident on the second wavelength selection element 30b, and the fourth inner mirror 20d is disposed so that the fourth laser beam Ld is perpendicularly incident on the second wavelength selection element 30b. As a result, the wavelengths of the laser beam Lc and the laser beam Ld can be stably narrowed to λ2. Further, a difference between a center wavelength selectable by the second wavelength selection element 30b and a center wavelength selectable by the first wavelength selection element 30a is in a range from 0.05 nm to 15 nm, and is preferably in a range from 1 nm to 5 nm. In this way, as described in FIG. 4A, the wavelength-combined beam of the wavelength beam combining device can be condensed at substantially the same position by the condensing lens 50. Thus, the combining efficiency in the optical fiber 60 can be improved.

The third outer mirror 40c is disposed outside the third external resonator, and allows the third laser beam Lc to be incident in the predetermined direction, in a manner same as or similar to the laser beams La and Lb. Similarly, the fourth outer mirror 40d is disposed outside the fourth external resonator and allows the fourth laser beam Ld to be incident in the predetermined direction. The laser beams La to Ld emitted from the light source device 100D1 correspond to the plurality of laser beams L emitted from the light source device 100D illustrated in FIG. 4A. The number of the laser beams La to Ld emitted from the light source device 100D1 is the same as the number of the light source units 10A to 10D.

In the wavelength beam combining device 200D according to the fourth embodiment, the two or more wavelength-combined beams formed by the pair of diffraction gratings 80A and 80B are incident in the predetermined direction in a manner same as or similar to the two or more laser beams of the respective wavelengths included in the plurality of laser beams L emitted from the light source device 100D. Thus, by disposing the condensing lens 50 so that the optical axis of the condensing lens 50 is parallel to the predetermined direction, the two or more wavelength-combined beams can be effectively combined in the optical fiber 60 by the condensing lens 50. As a result, a high-power laser beam can be obtained.

### Second Example of Light Source Device

FIG. 4C is a view illustrating a second example of the light source device 100D included in the wavelength beam combining device 200D illustrated in FIG. 4A. A light source device 100D2 illustrated in FIG. 4C is different from the light source device 100D1 illustrated in FIG. 4B in the following points. Specifically, the light source device 100D2 includes the first wavelength selection element 30a for selecting the wavelength of the laser beam La and the second wavelength selection element 30b for selecting the wavelength of the laser beam Lb, instead of the wavelength selection element common to the first light source unit 10A and the second light source unit 10B illustrated in FIG. 4B. The first wavelength selection element 30a stably narrows the laser beam La to λ1, and the second wavelength selection element 30b stably narrows the laser beam Lb to λ1. The first wavelength selection element 30a may be the first VHG and the second wavelength selection element 30b may be the second VHG. The first VHG and the second VHG may be the same VHG. The light source device 100D2 further includes a third wavelength selection element 30c for selecting the wavelength of the laser beam Lc, and a fourth wavelength selection element 30d for selecting the wavelength of the laser beam Ld, instead of the wavelength selection element common to the third light source unit 10C and the fourth light source unit 10D illustrated in FIG. 4B. The third wavelength selection element 30c stably narrows the wavelength of the laser beams Lc to λ2, and the fourth wavelength selection element 30d stably narrows the wavelength of the laser beam Ld to λ2. The third wavelength selection element 30c may be a third VHG and the fourth wavelength selection element 30d may be a fourth VHG. The third VHG and the fourth VHG may be the same VHG. Further, similarly to the light source device 100D1, the difference between the center wavelength selectable by the first wavelength selection element 30a and the second wavelength selection element 30b and the center wavelength selectable by the third wavelength selection element 30c and the fourth wavelength selection element 30d may be in a range from 0.05 nm to 15 nm, and is preferably in a range from 1 nm to 5 nm.

In the light source device 100D2, the wavelength selection elements 30a to 30d can be disposed in accordance with the bonding state of the light sources 10a to 10d to the support base 70. Thus, it is easy to dispose the inner mirrors 20a to 20d so that the laser beams La to Ld are perpendicularly incident on the wavelength selection elements 30a to 30d.

As described above, the light source devices 100D1 and 100D2 according to the fourth embodiment include the light source units 10A and 10B that emit the laser beams La and Lb of the certain wavelength, and the light source units 10C and 10D that emit the laser beams Lc and Ld of the other wavelength. The light source devices 100D1 and 100D2 further include the outer mirrors 40a and 40b that reflect the laser beams La and Lb of the certain wavelength, and the outer mirrors 40c and 40d that reflect the laser beams Lc and Ld of the other wavelength. Because the light source units 10A to 10D and the outer mirrors 40a to 40d are supported by the single support base 70, the number of components of the support base 70 can be reduced, and the cost of the components can be reduced.

### Fifth Embodiment

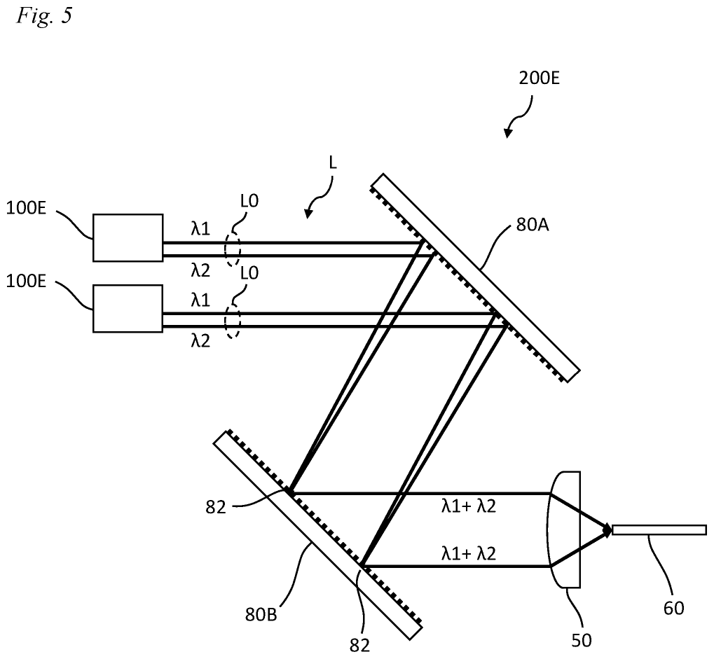

Next, a configuration example of a wavelength beam combining device including a plurality of light source devices according to a fifth embodiment of the present disclosure will be described with reference to FIG. 5.

### Wavelength Beam Combining Device

FIG. 5 is a view schematically illustrating the configuration of the wavelength beam combining device according to the exemplary fifth embodiment of the present disclosure. A wavelength beam combining device 200E illustrated in FIG. 5 includes a plurality of light source devices 100E, the pair of diffraction gratings 80A and 80B, the condensing lens 50, and the optical fiber 60. The wavelength beam combining device illustrated in FIG. 5 differs from the wavelength beam combining device illustrated in 3A in that each of the light source devices 100E emits at least the laser beams having the wavelength λ1 and the laser beam having the wavelength λ2, which are different from each other. The other points are the same.

As an example of the light source device 100E, a light source device 100C2 illustrated in FIG. 3C can be used. In this case, the first wavelength selection element 30a and the second wavelength selection element 30b select different wavelengths. That is, the first wavelength selection element 30a stably maintains the wavelength of the laser beam La that is perpendicularly incident on the first wavelength selection element 30a to λ1, and the second wavelength selection element 30b stably maintains the wavelength of the laser beam Lb that is perpendicularly incident on the second wavelength selection element 30b to λ2. In the wavelength beam combining device 200E, as the same as or similar to the wavelength beam combining device 200D illustrated in FIG. 4A, the difference between the wavelength λ2 and the wavelength λ1 may be in the range from 0.05 nm to 15 nm, and is preferably in the range from 1 nm to 5 nm.

As described above, in the wavelength beam combining device 200E according to the fifth embodiment, the one of the plurality of light source devices 100E emits the laser beam having the wavelength λ1 and the laser beam having the wavelength λ2 at the time of laser oscillation. The same applies to the other one of the plurality of light source devices 100E. The first diffraction grating 80A diffracts the two or more laser beams L0 emitted from each of the light source devices 100E and allows the diffracted laser beams L0 to be incident on the second diffraction grating 80B. The second diffraction grating 80B diffracts the two or more laser beams L0 emitted from each of the plurality of light source devices 100E and diffracted by the first diffraction grating 80A to form the two or more wavelength-combined beams.

The condensing lens 50 combines the laser beam having the wavelength λ1 and the laser beam having the wavelength λ2 emitted from the one of the plurality of light source devices 100E and diffracted by the second diffraction grating 80B, and also combines the laser beam having the wavelength λ1 and the laser beam having the wavelength λ2 emitted from the other one of the plurality of light source devices 100E and diffracted by the second diffraction grating 80B. The optical fiber 60 guides the laser beams having the wavelength λ1 and the laser beams having the wavelength λ2 combined by the condensing lens 50. As a result, a high-power laser beam can be obtained.

In the wavelength beam combining device 200E according to the fifth embodiment, the plurality of light source devices 100E have the same structure, and the two or more laser beams L0 having the different wavelengths are emitted from each of the light source devices 100E. Because the components are the same, procurement of the components is easy.

### Modified Example of Light Source Device 100A1

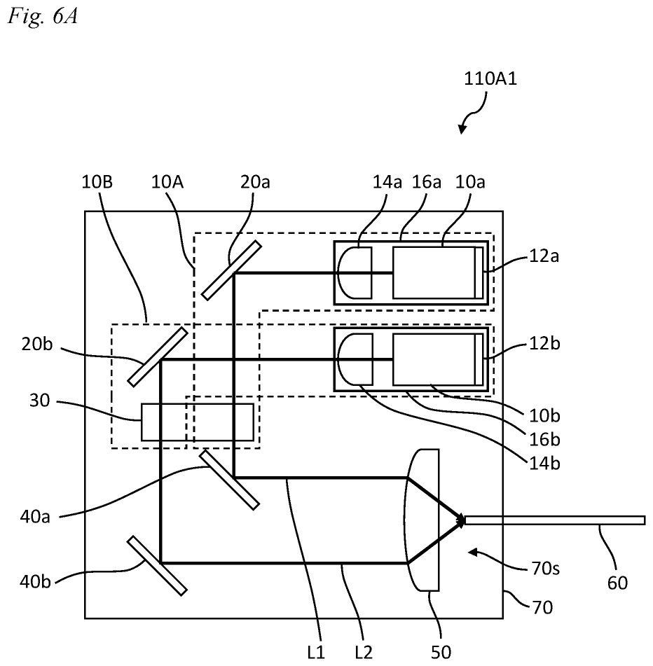

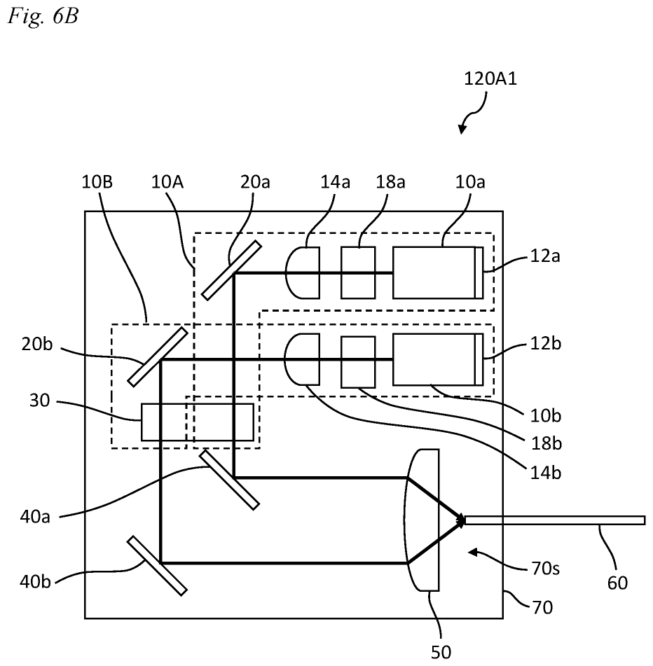

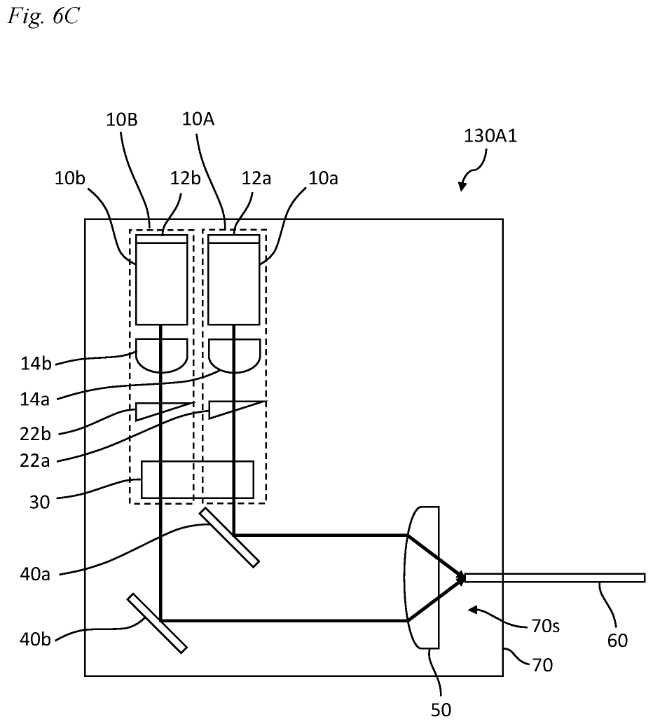

Next, first to third modified examples of the light source device 100A1 according to the first embodiment are described below with reference to FIGS. 6A to 6C.

### First Modified Example

FIG. 6A is a view schematically illustrating the first modified example of the light source device 100A1 according to the first embodiment. A light source device 110A1 illustrated in FIG. 6A is different from the light source device 100A1 illustrated in FIG. 1B in the following points. The first light source unit 10A included in the light source device 110A1 further includes a first package 16a that houses the first light source 10a and the first collimating lens 14a. Similarly, the second light source unit 10B included in the light source device 110A1 further includes a second package 16b that houses the second light source 10b and the second collimating lens 14b.

When the packages 16a and 16b seal the light sources 10a and 10b and the collimating lenses 14a and 14b, the durability of the light sources 10a and 10b and the collimating lenses 14a and 14b can be improved. This seal is preferably a hermetic seal. In the case of the hermetic seal, even if an organic bonding member is present outside the packages 16a and 16b, the organic bonding member does not enter inside the packages 16a and 16b. Thus, the inner mirrors 20a and 20b and the outer mirrors 40a and 40b disposed outside the packages 16a and 16b can be bonded to the support base 70 via the organic bonding member, such as a photocurable resin or a thermosetting resin. Using the organic bonding member makes adjustment of the positions and orientations of the inner mirrors 20a and 20b and the outer mirrors 40a and 40b easier compared to the inorganic bonding member, and also allows for easy rework when a mounting displacement occurs.

### Second Modified Example

FIG. 6B is a view schematically illustrating the second modified example of the light source device 100A1 according to the first embodiment. A light source device 120A1 illustrated in FIG. 6B is different from the light source device 100A1 illustrated in FIG. 1B in the following points. The first light source unit 10A included in the light source device 120A1 further includes a first beam twisting lens 18a disposed between the first light source 10a and the first inner mirror 20a. Similarly, the second light source unit 10B included in the light source device 120A1 further includes a second beam twisting lens 18b disposed between the second light source 10b and the second inner mirror 20b. In the example illustrated in FIG. 6B, the beam twisting lenses 18a and 18b are disposed between the light sources 10a and 10b and the collimating lenses 14a and 14b. The positions of the beam twisting lenses 18a and 18b and the collimating lenses 14a and 14b may be switched, and the beam twisting lenses 18a and 18b may be disposed between the collimating lenses 14a and 14b and the inner mirrors 20a and 20b, or a component in which the beam twisting lenses and the collimating lenses are integrated may be used.

The light sources 10a and 10b, the collimating lenses 14a and 14b, the beam twisting lenses 18a and 18b, the inner mirrors 20a and 20b, and the wavelength selection element 30 are directly or indirectly supported by the surface 70s of the support base 70. The light sources 10a and 10b, the collimating lenses 14a and 14b, the beam twisting lenses 18a and 18b, the inner mirrors 20a and 20b, and the wavelength selection element 30 are directly or indirectly supported in the plane at the same height, with respect to the lower surface of the support base 70 as the reference height. Because it is not necessary to provide a stepped-shape step at the surface 70s, processing of the support base 70 is easy.

The beam twisting lenses 18a and 18b switch the fast-axis direction and the slow-axis direction of the laser beams La and Lb passing therethrough. When the emission surfaces of the light sources 10a and 10b have a rectangular shape elongated in a direction parallel to the surface 70s of the support base 70, the fast-axis direction of the laser beams La and Lb emitted from the light sources 10a and 10b is perpendicular to the surface 70s, and the slow-axis direction is parallel to the surface 70s. In contrast to this, the fast-axis direction of the laser beams La and Lb that have passed through the beam twisting lenses 18a and 18b is parallel to the surface 70s, and the slow-axis direction thereof is perpendicular to the surface 70s.

The laser beams La and Lb that have passed through the beam twisting lenses 18a and 18b correspond to laser beams emitted from virtual emission surfaces having a rectangular shape extending in a direction perpendicular to the surface 70s of the support base 70. Because the virtual emission surfaces are relatively narrow in a direction parallel to the surface 70s and relatively wide in a direction perpendicular to the surface 70s, they can be treated as point light sources in a plane parallel to the surface 70s. The laser beams La and Lb emitted from the point light sources can be collimated by the collimating lenses 14a and 14b having short focal distances. This is because focal points of the collimating lenses 14a and 14b can be allowed to be substantially coincident with the point light sources. As a result, the spread of the laser beams La and Lb in the direction parallel to the surface 70s can be effectively reduced.

Thus, after passing through the beam twisting lenses 18a and 18b and the collimating lenses 14a and 14b, the widths of the laser beams La and Lb in the direction parallel to the surface 70s can be made smaller than the widths of the laser beams La and Lb in the direction perpendicular to the surface 70s, and thus the pitch between the first and second laser beams incident on the outer mirrors 40a and 40b in the predetermined direction can be narrowed. In this way, when the number of the light sources 10a and 10b is increased, the plurality of laser beams can be allowed to be incident on the condensing lens 50 with a high density, and the higher power laser beam can be extracted from the light source device 120A1.

### Third Modified Example

FIG. 6C is a view schematically illustrating the third modified example of the light source device 100A1 according to the first embodiment. A light source device 130A1 illustrated in FIG. 6C is different from the light source device 100A1 illustrated in FIG. 1B in the following points. Specifically, the first light source unit 10A included in the light source device 130A1 includes a first wedge 22a instead of the first inner mirror 20a. Similarly, the second light source unit 10B included in the light source device 130A1 includes a second wedge 22b instead of the second inner mirror 20b.

Each of the wedges 22a and 22b has a light incident surface and a light emission surface that are not parallel to each other. The wedges 22a and 22b change the traveling directions of the laser beams La and Lb passing through the respective wedges 22a and 22b, using refraction. By changing the traveling directions of the laser beams La and Lb using the refraction by the wedges 22a and 22b, the laser beams La and Lb can be allowed to be perpendicularly incident on the wavelength selection element 30.

In the light source device 130A1, as compared with the light source device 100A1, the outer mirrors 40a and 40b are not changed, and the inner mirrors 20a and 20b are changed to the wedges 22a and 22b. Conversely, the outer mirrors 40a and 40b may be changed to wedges without changing the inner mirrors 20a and 20b. Alternatively, the wedges 22a and 22b may be used instead of the inner mirrors 20a and 20b, and the wedges may also be used instead of the outer mirrors 40a and 40b. Because it is not always necessary to use mirrors for adjusting the optical paths of the laser beams La and Lb, a range of selection of components is widened. Further, although the wedges 22a and 22b acting in a direction parallel to the surface 70s of the support base 70 are illustrated, wedges acting in a direction perpendicular to the surface 70s may be used, or both these wedges may be used.

In the present specification, the optical elements, such as the inner mirrors 20a to 20d and the wedges 22a and 22b, that adjust the optical paths of the laser beams La to Ld in the external resonators included in the light source units 10A to 10D are referred to as “internal optical path adjusting elements.” Further, optical elements, such as the outer mirrors 40a to 40d and the wedges 22a and 22b, that adjust the optical paths of the laser beams La to Ld outside the external resonators included in the light source units 10A to 10D are referred to as “external optical path adjusting elements.”

Although the first to third modified examples of the light source device 100A1 have been described above, each of the modified examples may also be applied to the other light source devices 100A2, 100C1, 100C2, 100D1, and 100D2.

The wavelength beam combining device and the light source device have been described above. The wavelength beam combining device includes at least one type of the above-described light source devices. Further, the wavelength beam combining device may include two or more types of the above-described light source device. The wavelength selected by the wavelength selection element included in each of the light source devices is appropriately adjusted in consideration of the use thereof in the wavelength beam combining device.

The light source device and the wavelength beam combining device according to the present disclosure are applicable to industrial fields where a high-power laser light source is required, such as the cutting or hole-making of various materials, local heat treatment, surface treatment, welding of metal, 3D printing, exposure device, and the like.

What is claimed is:

1. A wavelength beam combining device comprising:
a plurality of light source devices; and
a diffraction grating configured to perform wavelength beam combining of a plurality of laser beams emitted from the plurality of light source devices; wherein:
at least one of the plurality of light source devices comprises:
a first light source unit comprising:
a first external resonator formed by a first wavelength selection element and a first resonator mirror,
a first light source disposed in the first external resonator and configured to emit a first laser beam during laser oscillation, and
a first internal optical path adjusting element that is disposed between the first wavelength selection element and the first light source in the first external resonator and is configured to allow the first laser beam to be incident on the first wavelength selection element,
a second light source unit comprising:
a second external resonator formed by the first wavelength selection element and a second resonator mirror,
a second light source disposed in the second external resonator and configured to emit a second laser beam during laser oscillation, and
a second internal optical path adjusting element that is disposed between the first wavelength selection element and the second light source in the second external resonator and is configured to allow the second laser beam to be incident on the first wavelength selection element,
a first external optical path adjusting element that is disposed outside the first external resonator and is configured to allow the first laser beam to be incident in a predetermined direction, and
a second external optical path adjusting element that is disposed outside the second external resonator and is configured to allow the second laser beam to be incident in a predetermined direction.

2. The wavelength beam combining device according to claim 1, wherein:
the first wavelength selection element is a volume holographic grating;
the first internal optical path adjusting element is configured to allow the first laser beam to be perpendicularly incident on the first wavelength selection element; and
the second internal optical path adjusting element is configured to allow the second laser beam to be perpendicularly incident on the first wavelength selection element.

3. The wavelength beam combining device according to claim 1, wherein:
the at least one of the plurality of light source devices comprises:
a third light source unit comprising:
a third external resonator formed by a second wavelength selection element and a third resonator mirror,
a third light source disposed in the third external resonator and configured to emit a third laser beam during laser oscillation, and
a third internal optical path adjusting element that is disposed between the second wavelength selection element and the third light source in the third external resonator and is configured to allow the third laser beam to be incident on the second wavelength selection element,
a fourth light source unit comprising:
a fourth external resonator formed by the second wavelength selection element and a fourth resonator mirror,
a fourth light source disposed in the fourth external resonator and configured to emit a fourth laser beam during laser oscillation, and
a fourth internal optical path adjusting element that is disposed between the second wavelength selection element and the fourth light source in the fourth external resonator and is configured to allow the fourth laser beam to be incident on the second wavelength selection element,
a third external optical path adjusting element that is disposed outside the third external resonator and is configured to allow the third laser beam to be incident in a predetermined direction, and
a fourth external optical path adjusting element that is disposed outside the fourth external resonator and is configured to allow the fourth laser beam to be incident in a predetermined direction.

4. The wavelength beam combining device according to claim 3, wherein:
the second wavelength selection element is a volume holographic grating;
the third internal optical path adjusting element allows the third laser beam to be perpendicularly incident on the second wavelength selection element; and
the fourth internal optical path adjusting element allows the fourth laser beam to be perpendicularly incident on the second wavelength selection element.

5. The wavelength beam combining device according to claim 1, wherein:
the first light source unit comprises a first collimating lens disposed between the first light source and the first internal optical path adjusting element and configured to collimate the first laser beam; and
the second light source unit comprises a second collimating lens disposed between the second light source and the second internal optical path adjusting element and configured to collimate the second laser beam.

6. The wavelength beam combining device according to claim 5, wherein:
the first light source unit further comprises a first beam twisting lens disposed between the first light source and the first internal optical path adjusting element;
the second light source unit further comprises a second beam twisting lens disposed between the second light source and the second internal optical path adjusting element;
the at least one of the plurality of light source devices further comprises a support base that supports the first light source unit and the second light source unit on an upper surface thereof; and
the first light source, the second light source, the first internal optical path adjusting element, the second internal optical path adjusting element, the first collimating lens, the second collimating lens, the first beam twisting lens, and the second beam twisting lens are supported on a plane at the same height with respect to a lower surface of the support base.

7. The wavelength beam combining device according to claim 1, further comprising:
a condensing lens configured to combine the first laser beam adjusted by the first external optical path adjusting element and the second laser beam adjusted by the second external optical path adjusting element; and
an optical fiber configured to guide the first laser beam and the second laser beam that are combined by the condensing lens.

8. The wavelength beam combining device according to claim 1, wherein:
the first internal optical path adjusting element is a first inner mirror;
the second internal optical path adjusting element is a second inner mirror;
the first external optical path adjusting element is a first outer mirror; and
the second external optical path adjusting element is a second outer mirror.

9. The wavelength beam combining device according to claim 1, wherein:
the first internal optical path adjusting element is a first wedge;
the second internal optical path adjusting element is a second wedge;
the first external optical path adjusting element is a first outer mirror; and
the second external optical path adjusting element is a second outer mirror.

10. The wavelength beam combining device according to claim 1, wherein:
the diffraction grating comprises a first diffraction grating and a second diffraction grating;
the first diffraction grating is configured to diffract a plurality of laser beams including the first laser beam and the second laser beam in different directions according to a wavelength, and allows the plurality of laser beams to be incident on the second diffraction grating; and
the second diffraction grating is configured to diffract the plurality of laser beams diffracted by the first diffraction grating to form a wavelength-combined beam.

11. The wavelength beam combining device according to claim 10, wherein:
a first of the plurality of light source devices is configured to emit a laser beam having a first wavelength and a laser beam having a second wavelength, and
a second of the plurality of light source devices is configured to emit a laser beam having the first wavelength and a laser beam having the second wavelength.

12. The wavelength beam combining device according to claim 11, comprising:
a condensing lens configured to combine (i) the laser beam having the first wavelength and the laser beam having the second wavelength that are emitted from the first of the plurality of light source devices and are diffracted by the second diffraction grating, and to combine (ii) the laser beam having the first wavelength and the laser beam having the second wavelength that are emitted from the second of the plurality of light source devices and are diffracted by the second diffraction grating; and
an optical fiber configured to guide the laser beam having the first wavelength and the laser beam having the second wavelength that are combined by the condensing lens.

13. A wavelength beam combining device comprising:
a plurality of light source devices; and
a diffraction grating configured to perform wavelength beam combining of a plurality of laser beams emitted from the plurality of light source devices, wherein:
at least one of the plurality of light source devices comprises:
a first light source unit comprising:
a first external resonator formed by a first wavelength selection element and a first resonator mirror,
a first light source disposed in the first external resonator and configured to emit a first laser beam during laser oscillation, and
a first internal optical path adjusting element that is disposed between the first wavelength selection element and the first light source in the first external resonator and is configured to allow the first laser beam to be incident on the first wavelength selection element,
a second light source unit comprising:
a second external resonator formed by a second wavelength selection element and a second resonator mirror,
a second light source disposed in the second external resonator and configured to emit a second laser beam during laser oscillation, and
a second internal optical path adjusting element that is disposed between the second wavelength selection element and the second light source in the second external resonator and is configured to allow the second laser beam to be incident on the second wavelength selection element,
a first external optical path adjusting element that is disposed outside the first external resonator and is configured to allow the first laser beam to be incident in a predetermined direction, and
a second external optical path adjusting element that is disposed outside the second external resonator and is configured to allow the second laser beam to be incident in a predetermined direction.

14. The wavelength beam combining device according to claim 13, wherein:
the first wavelength selection element is a first volume holographic grating;
the second wavelength selection element is a second volume holographic grating;
the first internal optical path adjusting element allows the first laser beam to be perpendicularly incident on the first wavelength selection element; and
the second internal optical path adjusting element allows the second laser beam to be perpendicularly incident on the second wavelength selection element.

15. The wavelength beam combining device according to claim 13, wherein:
the first internal optical path adjusting element is a first inner mirror;
the second internal optical path adjusting element is a second inner mirror;
the first external optical path adjusting element is a first outer mirror; and
the second external optical path adjusting element is a second outer mirror.

16. The wavelength beam combining device according to claim 13, wherein:
the diffraction grating comprises a first diffraction grating and a second diffraction grating;
the first diffraction grating is configured to diffract a plurality of laser beams including the first laser beam and the second laser beam in different directions according to a wavelength, and allows the plurality of laser beams to be incident on the second diffraction grating, and
the second diffraction grating is configured to diffract the plurality of laser beams diffracted by the first diffraction grating to form a wavelength-combined beam.
